(19) United States
(12) Patent Application Publication
(10) Pub. No.: US 2010/0151601 A1
(43) Pub. Date: Jun. 17, 2010

(54) APPARATUS FOR HARDENING SEAL OF ELECTROPHORETIC DISPLAY DEVICE AND METHOD OF FABRICATING ELECTROPHORETIC DISPLAY DEVICE USING THEREOF

(76) Inventors: Duk-Hyun PARK, Daegu (KR); Jae-Soo PARK, Seoul (KR)

Correspondence Address: MORGAN LEWIS & BOCKIUS LLP, 1111 PENNSYLVANIA AVENUE NW, WASHINGTON, DC, 20004, US

(21) Appl. No.: 12/636,042

(22) Filed: Dec. 11, 2009

(30) Foreign Application Priority Data
Dec. 12, 2008 (KR) 10-2008-0126761

(51) Int. Cl. H01L 33/52; B01J 19/12; F27D 5/00

(52) U.S. Cl. 438/26; 250/453.11; 432/253; 257/E33.059

(57) ABSTRACT

In an apparatus for curing a seal in an electrophoretic display device according to the present invention, a support having magnetism may be provided on a curing table to be loaded with an electrophoretic display device in order to support the electrophoretic display device while at the same time generating a magnetic force in a direction opposite to a stress caused by a seal material in the electrophoretic display device, thereby preventing the electrophoretic display device from being bent when the seal material is cured.

### CROSS-REFERENCE TO RELATED APPLICATIONS

Pursuant to 35 U.S.C. §119(a), this application claims the benefit of earlier filing date and right of priority to Korean Application No. 10-2008-0126761 filed on Dec. 12, 2008, the contents of which are incorporated by reference herein in its entirety.

### BACKGROUND OF THE INVENTION

1. Field of the Invention

The present invention relates to an apparatus for curing a seal in an electrophoretic display device, and a method of fabricating an electrophoretic display device using the same, and more particularly, to an apparatus for curing a seal in an electrophoretic display device, and a method of fabricating an electrophoretic display device using the same, capable of preventing the electrophoretic display device from being bent by a stress caused during a seal curing process.

2. Description of the Related Art

In general, an electrophoretic display device is an image display device using a phenomenon that colloidal particles move to either one of the polarities when one pair of electrodes to which a voltage is applied are immersed into a colloidal solution. The electrophoretic display device in which a backlight is not used, but having characteristics such as wide viewing angle, high reflectivity, low power consumption, and the like, and thus it is widely used as an electronic device such as electronic paper.

The electrophoretic display device has a structure in which an electronic ink layer is interposed between two substrates, and at least one of the two substrates is made of a transparent substrate and the other substrate is provided with a reflection plate to display images in a reflective mode in which incident light is reflected.

FIG. 1 is a cross-sectional view illustrating a related electrophoretic display device. In actuality, a plurality of pixels defined by a plurality of gate lines and data lines arranged vertically and horizontally to receive signals from the outside are arranged in an electrophoretic display device, but in the drawing, it is shown only one pixel for the sake of convenience of explanation.

As illustrated in FIG. 1, a electrophoretic display device 1 includes a first substrate 20 and a second substrate 32, and the first substrate 20 is a substrate made of glass, or the like, and the second substrate 32 is made of a transparent flexible film such as PET.

A thin-film transistor and a pixel electrode 18 are formed on the first substrate 20, and a signal is applied to the pixel electrode 18 through the thin-film transistor from the outside. The thin-film transistor includes a gate electrode 10 formed on the first substrate 20, a gate insulation substrate 22 formed over the overall first substrate 20 that is formed with the gate electrode 10, a semiconductor layer 12 formed on the gate insulation substrate 22, and a source electrode 14 and a drain electrode 15 formed on the semiconductor layer 12. A protection layer 24 is formed on the thin-film transistor, that is, the source electrode 14 and the drain electrode 15.

A pixel electrode 18 is formed on the protection layer 24, and the pixel electrode 18 is electrically connected to a drain electrode 15 of a thin-film transistor through a contact hole formed on the protection layer 24.

A common electrode 34 and an electronic ink layer 35 made of a transparent conductive material are formed on the second substrate 32. The electronic ink layer 35 is in a film shape in which capsules 37 filled with electronic ink in a polymer binder are distributed, and the electronic ink distributed in the capsules 37 consists of white particles (or white ink) 38 and black particles (or black ink) 39. At this time, the white particles 38 and black particles 39 have the characteristics of positive and negative charges, respectively. In other words, the white particles 38 are positively charged, and the black particles 39 are negatively charged.

In this manner, a film for forming a common electrode 34 and an electronic ink layer 35 on the second substrate 32 is called a front plane laminate (FPL) 1, and hereinafter, a second substrate 32 on which the common electrode 34 and the electronic ink layer 35 are formed is commonly designated as a FPL film.

A protection film 36 is attached to an upper portion of the FPL film 30, thereby preventing moisture from being infiltrated into the electronic ink layer 35.

The common electrode 34 faces the pixel electrode 18 of the first substrate 20, and if a signal is applied to the pixel electrode 18, then an electric field is formed in cooperation with the pixel electrode 18 to apply the electric field to the electronic ink layer 35, and as a result, the white particles 38 and black particles 39 in the capsules 37 are moved by the electric field in order to display an image.

Furthermore, a common line 26 allowing a common signal to be applied from the outside is formed, and an Ag-dotting portion making contact with the common electrode 34 of the second substrate 32 is disposed on the common line 26 to apply a common signal inputted through the common line 26 to the common electrode 34 of the FPL film 30.

The FPL film 30 having the foregoing configuration is attached to the first substrate 20 and the protection film 36 is attached on the FPL film 30, and then a seal material 29 is coated and cured between the first substrate 20 and the protection film 36 to seal the first substrate 20 and the FPL film 30, thereby finishing an electrophoretic display device 1. The seal material 29 is cured by heat, and the curing is made by placing a plurality of the fabricated electrophoretic display devices on a seal material curing table and then applying heat.

On the other hand, in recent years, the demand for flexible electrophoretic display devices has been increased, and a metal plate such as stainless steel is used for the first substrate 20 in order to fabricate such a flexible electrophoretic display device, instead of using glass. When a metal plate is used for the first substrate, it may be possible to obtain a flexible electrophoretic display device because the glass does not provide flexibility but the metal plate provides flexibility. However, a method of heat-curing a seal material in a conventional electrophoretic display device fabricated with a metal plate has a problem as follows.

FIG. 2 is a conceptual diagram schematically illustrating a process of curing a seal material in a conventional electrophoretic display device made of a metal plate. As illustrated in FIG. 2, an electrophoretic display device 1 in which a FPL film 30 and a protection film 36 are attached to a first substrate 20 by a seal material is loaded on a seal curing table 50, and then heat is applied in order to cure the seal material.

As illustrated in FIG. 3A, the electrophoretic display device maintains a flat state in an initial state that a seal material is coated. However, a stress will be applied to the seal material of the electrophoretic display device, as the curing of the seal material is progressed. At this time, a thickness of the metal plate, which is a first substrate 20, is about 0.15 mm, and a thickness of the FPL film 30, which is a second substrate 32, is about 0.3 mm, and a thickness of the protection film 36 is about 0.3 mm. Accordingly, when the seal material is cured, a stress is generated in an upward direction at the seal material of the electrophoretic display device, and thus an edge region of the electrophoretic display device is bent by the stress, thereby causing a defective electrophoretic display device.

### SUMMARY OF THE INVENTION

The present invention is contrived to solve the aforementioned problem, and an object of the invention is to provide an apparatus for curing a seal material in an electrophoretic display device, and a method of fabricating an electrophoretic display device using the same, in which a magnetic force is generated in a direction opposite to a stress caused by a seal material when the seal material is cured, thereby preventing the electrophoretic display device from being bent.

In order to accomplish the foregoing object, an apparatus for curing a seal material in an electrophoretic display device according to the present invention may include an electrophoretic display panel including a substrate made of metal and formed with thin-film transistors, a front plane laminate (FPL) film made of a transparent sheet and an electronic ink film attached to the transparent sheet, a protection film attached to the FPL film, and a seal material formed between the substrate and the protection film for sealing the substrate and the protection film; a curing table to be loaded with at least one electrophoretic display panel; a curing unit for curing a seal material in an electrophoretic display panel loaded on the curing table; and a support formed on the curing table for loading the electrophoretic display panel to apply a magnetic force in a direction opposite to a stress by the seal material to the electrophoretic display panel.

Furthermore, a method of fabricating an electrophoretic display device according to the present invention may include the steps of forming thin-film transistors and electrodes on each panel region of a mother substrate made of a metal plate including a plurality of panel regions; forming a common electrode and adhering an electronic ink film on a transparent sheet to form a front plane laminate (FPL) film; cutting the mother substrate to divide into a plurality of display panels; adhering a FPL film and a protection film to the divided display panel; coating a seal material on the display panel attached with the FPL film and protection film; and loading the display panel coated with the seal material on a curing table formed with a support for applying a magnetic force to cure the seal material, wherein a direction of the magnetic force applied by the support is opposite to the direction of a stress caused by the seal material.

According to the present invention, a magnetic force is generated in a direction opposite to a stress caused by a seal material when the seal material is cured, thereby preventing the electrophoretic display device from being bent.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a cross-sectional view illustrating a conventional electrophoretic display device;

FIG. 2 is a conceptual diagram schematically illustrating a process of curing a seal material in a conventional electrophoretic display device made of a metal plate;

FIGS. 3A and 3B are views illustrating a process of curing a seal material in a conventional electrophoretic display device;

FIG. 4 is a flow chart illustrating a method of fabricating an electrophoretic display device according to an embodiment of the present invention;

FIG. 5 is a view illustrating a plurality of electrophoretic display panels formed on a mother substrate;

FIG. 6 is a view illustrating an apparatus for curing a seal material in an electrophoretic display device according to the present invention;

FIG. 7 is a plan view illustrating a curing table as illustrated in FIG. 6; and

FIG. 8 is a view illustrating a method of fabricating an electrophoretic display device according to another embodiment of the present invention.

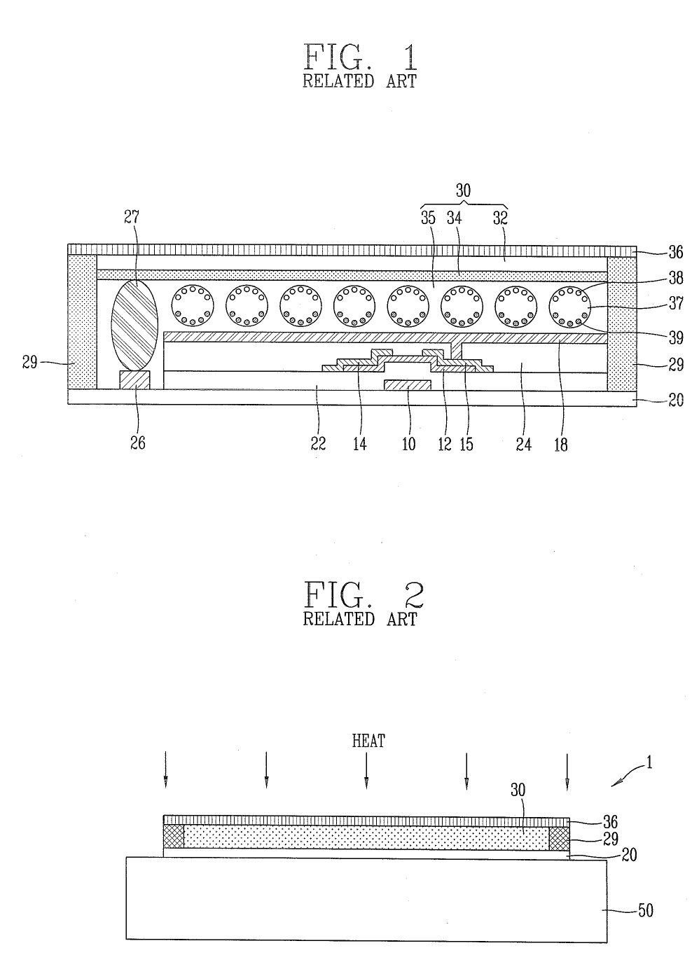

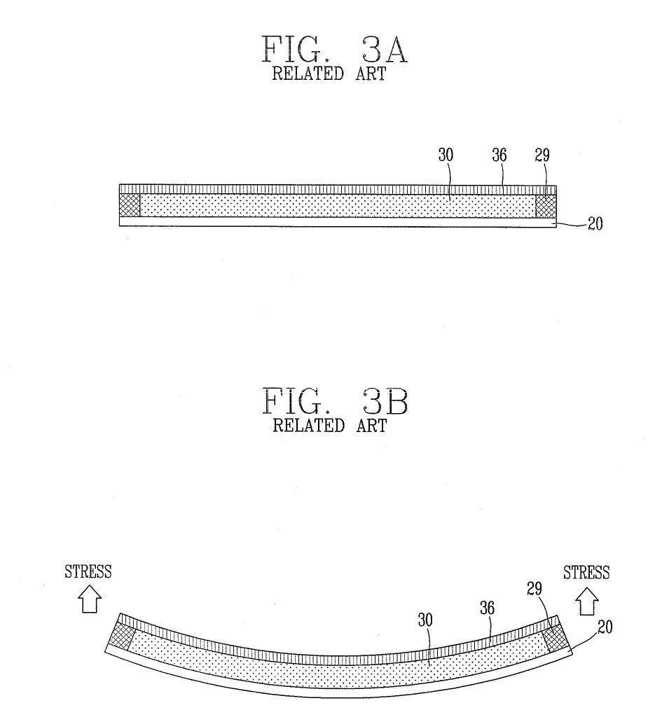

### DETAILED DESCRIPTION OF THE INVENTION

Hereinafter, the present invention will be described in detail with reference to the accompanying drawings.

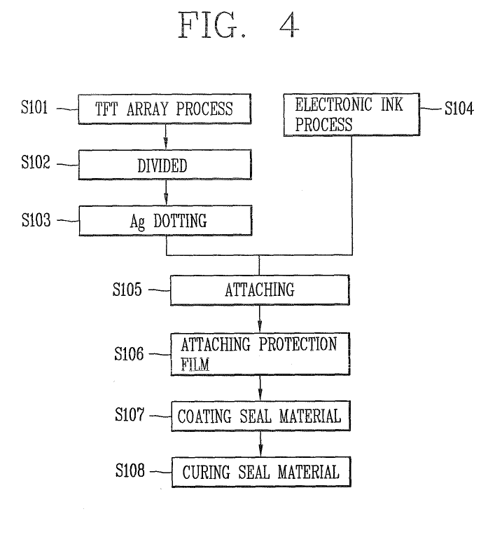

FIG. 4 is a flow chart illustrating a method of fabricating an electrophoretic display device according to an embodiment of the present invention.

As illustrated in FIG. 4, in a method of fabricating an electrophoretic display device according to an embodiment of the present invention, a substrate formed with TFTs and a FPL film are passed through different processes, and then attached to each other in the attachment process, thereby producing an electrophoretic display device.

At this time, the substrate formed with TFTs is a flexible metal plate such as stainless steel and the process thereof is performed in a mother substrate unit, on which a plurality of electrophoretic display panels are formed, whereas a substrate formed with an electronic ink layer is a transparent film and the process thereof is performed by each piece in a display panel unit.

As illustrated in FIG. 4, first, in the TFT array process, thin-film transistors and various wirings and electrodes are formed on each of a plurality of panel regions 101 of a mother substrate (S101). At this time, the thin-film transistors and various wirings and electrodes are formed by a typical photolithographic process.

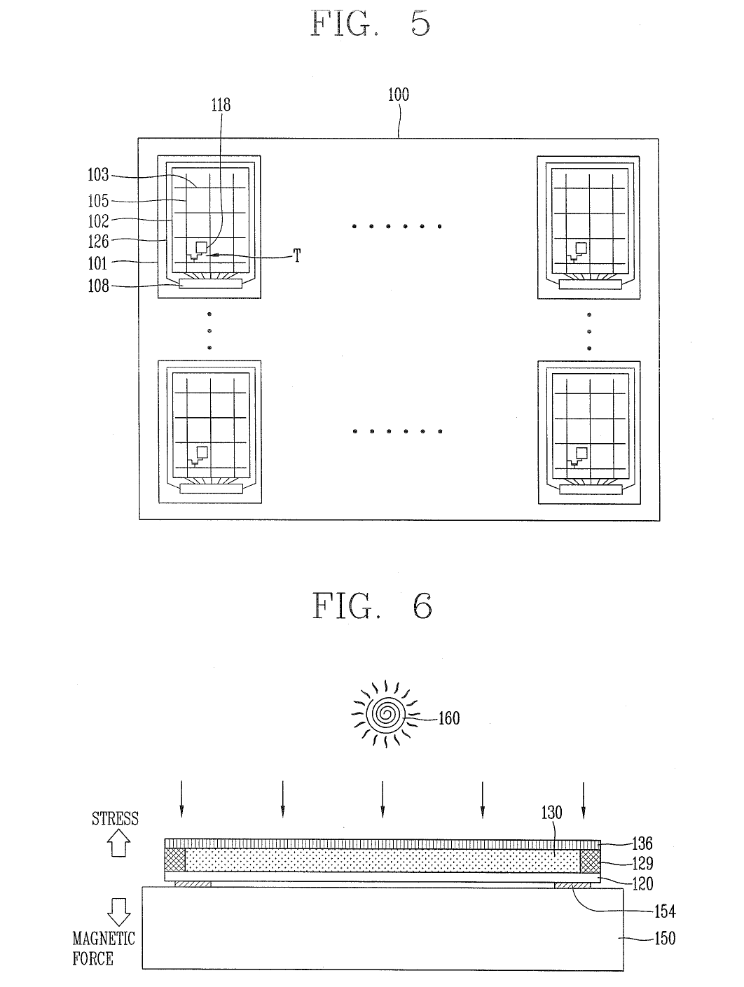

In FIG. 5, there is disclosed a structure in which thin-film transistors and the like are formed on each of the panel regions 101 of a mother substrate by the TFT array process. Even though two columns of panel regions 101 are formed in a mother substrate 100 in the drawing, it is not limited to such a structure of the mother substrate 100 according to the present invention. Three columns or more panel regions 101 may be arranged in a mother substrate 100 of the present invention, and the number of such panel regions 101 will not be limited.

As illustrated in FIG. 5, a display panel may be formed on each of a plurality of panel regions 101 of a mother substrate by the TFT array process. Each of the panel regions 101 is formed with a display region 102 forming a plurality of pixels to implement actual images, a pad 108 connected to an external drive element for applying a signal to the display region 102, and a common line 126 for inputting a common signal from the outside. The display region 102 is formed with a plurality of gate lines 103 and data lines 105 vertically and horizontally arranged for defining a plurality of pixels, a thin-film transistor (T) disposed at each pixel and connected to the gate lines 103 and data lines 105, and a pixel electrode 118 disposed at each pixel.

Though not shown in the drawing, the thin-film transistor (T) may include a gate electrode formed at the mother substrate 100, a gate insulation layer formed on the gate electrode, a semiconductor layer formed on the gate insulation layer, and a source electrode and a drain electrode formed on the semiconductor layer. At this time, the gate lines 103 are formed by the same process as that of the gate electrode of the thin-film transistor (T), and the data lines 105 are formed by the same process as that of the source electrode and drain electrode of the thin-film transistor (T). The pixel electrode 118 is connected to a drain electrode of the thin-film transistor, and a signal inputted through the thin-film transistor is applied to the pixel electrode 118. Furthermore, the common line 126 and pad 108 are formed by the same process as that of the gate electrode or source electrode of the thin-film transistor.

As described above, the mother substrate 100 formed with various elements such as thin-film transistor (T) on a plurality of panel regions 101 is cut into the panel region 101 by a cutting device and divided into each display panel (S102), Then, a silver dot is dotted on the common line 126 in each of the divided display panels (S103).

On the other hand, in the electronic ink layer forming line, a transparent conductive material is laminated on a plurality of transparent sheets, such as PET, corresponding to the number of the panel regions 101 formed on the mother substrate to form a common electrode, and then an electronic ink film is attached to the common electrode to form a FPL film (S105).

The electronic ink layer is made of a polymer binder, and capsules filled with electronic ink distributed in the polymer binder. The electronic ink distributed in the capsule consists of positively-charged white particles and negatively-charged black particles.

As described above, a FPL film attached with the electronic ink film is attached to each of the divided display panels by an attachment layer formed on the FPL film, and a protection film is attached to a front surface of the FPL film (S105, S106).

Subsequently, a seal material is coated between the substrate and the protection film, and then the coated seal material is cured to seal the substrate and FPL film, thereby finishing an electrophoretic display device (S107, S108).

In an electrophoretic display device fabricated as described above, if a scan signal is applied through a gate line from an external drive element, then a thin-film transistor formed at each pixel of the electrophoretic display device is activated to form a channel, and at the same time, if an image signal is applied through a data line from an external element, then the image signal is applied to the pixel electrode through a source electrode, a channel, and a drain electrode of the thin-film transistor. At this time, a common signal is applied to a common electrode formed on the FPL film through a common line to form an electric field between the pixel electrode and the common electrode. By this electric field, white and black particles distributed in the capsules of the electronic ink film are moved in an upward or downward direction, thereby displaying a desired image.

Because a first substrate of the electrophoretic display device is made of a metal plate and a FPL film thereof is made of a transparent sheet, the electrophoretic display device may be bent by a stress generated in a seal material when the seal material is cured. However, in this invention, a force is applied in a direction opposite to a stress generated in a seal material when the seal material is cured, thereby preventing the electrophoretic display device from being bent.

FIG. 6 is a view illustrating an seal material curing apparatus used in the present invention and a process of curing a seal material using the same. In the drawing, for the sake of convenience of explanation, there is schematically illustrated a structure of an electrophoretic display device.

As illustrated in FIG. 6, a seal material curing apparatus may include a curing table 150 on which an electrophoretic display device having a substrate 120 and a FPL film 130 attached to each other by a seal material is placed, a support 154 provided on the curing table 150 to support the electrophoretic display device while at the same time generating a magnetic force to the electrophoretic display device, and a heating unit 160 for applying heat to the electrophoretic display device placed on the curing table 150 to cure the seal material 129 of the electrophoretic display device.

Though not shown in the drawing, the substrate 120 is made of a metal plate, and thin-film transistors and electrodes are formed on an upper surface thereof, and the FPL film 130 is made of a common electrode formed on a transparent sheet and an electronic ink film attached thereon. Furthermore, as shown in the drawing, a protection film 136 is attached on the FPL film 130, and a seal material 129 is coated between an edge of the substrate 120 and the protection film 136.

The curing table 150 may be formed with various materials, but it is preferably formed with a material having resistance to heat applied when curing a seal material. Furthermore, the seal material in a plurality of electrophoretic display devices is cured on the curing table 150, and therefore, any size or shape thereof may be used so long as a plurality of electrophoretic display devices can be loaded. The curing table 150 is formed in a plate shape having a predetermined thickness as illustrated in the drawing, but it may be also configured such that the curing table 150 is formed with no ground plane but only having an edge with a predetermined thickness, and a plurality of supports 154 are provided on the edge. In this manner, in case of a configuration with no ground plane but only having an edge, heat may be uniformly applied to an upper or lower portion of the electrophoretic display device, thereby obtaining an effect of uniformly curing the seal material.

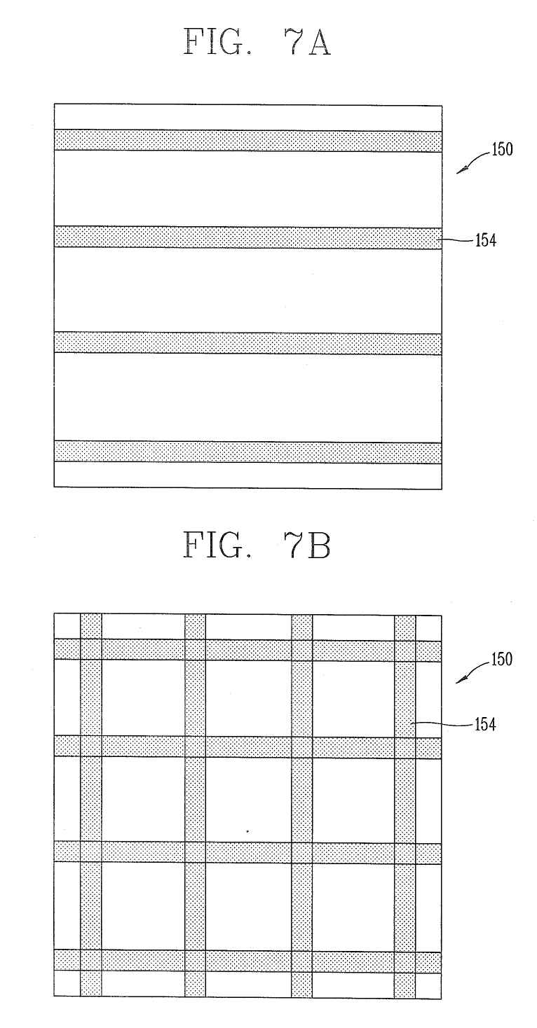

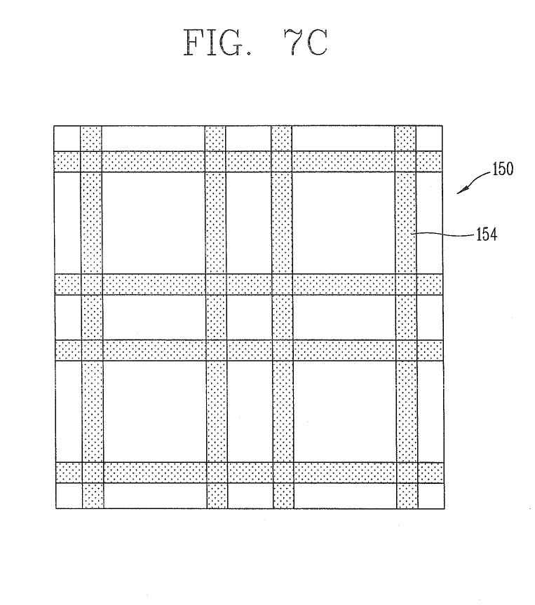

FIGS. 7A through 7C are views illustrating a structure in which a support is formed in various shapes on the curing table 150 applied to the present invention.

As illustrated in FIG. 7A, in the curing table 150, a plurality of supports 154 are arranged at regular intervals in a line to support a plurality of electrophoretic display devices to be loaded. The support 154 is placed with an electrophoretic display device having a seal material to be cured to support the electrophoretic display device, as well as made of a magnetic resin having a low magnetism of about 400-1000 gauss to apply a magnetic force to the electrophoretic display device. In this manner, the support 154 is made of a magnetic resin, and therefore, an electrophoretic display device, in which the substrate is made of a metal plate, is attached by magnetism to the magnetic resin while at the same time a shock generated between the electrophoretic display device and the supports 154 being smoothly absorbed by the magnetic resin.

When an electrophoretic display device is loaded on a curing table 150 having the foregoing structure, both sides of the electrophoretic display device are placed on the support 154 and a magnetic force is applied to the metal plate disposed at both sides of the electrophoretic display device. Though a seal material is coated on an overall edge of the electrophoretic display device and a stress is thereby generated by the overall seal material when the seal material is cured, the magnetic force is generated in a downward direction by the support 154 at both sides of the electrophoretic display device, and four edges of the electrophoretic display device are fixed by the magnetic force of the support 154, thereby preventing the electrophoretic display device from being bent by the stress.

In the drawing, a plurality of supports 154 are arranged in a horizontal direction, but may be arranged in a vertical direction.

As illustrated in FIG. 7B, the supports 154 may be horizontally and vertically arranged at regular intervals, namely, in a matrix shape. In this manner, in case where the supports 154 are horizontally and vertically arranged, four sides of an electrophoretic display device loaded on the support 154 are placed on the supports 154, and thus a magnetic force is acted upon an overall edge of the electrophoretic display device, thereby further easily preventing the electrophoretic display device from being bent by a stress. In this manner, in case where the supports 154 are horizontally and vertically arranged, a desired sized of magnetic force may be provided to the electrophoretic display device even though the supports 154 are formed with a magnetic resin having a lower magnetism, compared to a case where the supports 154 are horizontally or vertically arranged.

On the other hand, electrophoretic display devices having a predetermined size are not only always loaded on the curing table 150, but also electrophoretic display devices having various sizes are loaded in order for the seal material to be cured. Accordingly, in the present invention, the supports 154 as illustrated in FIGS. 7A and 7B are provided on the curing table 150 in a horizontally and/or vertically movable manner and thus a distance between the supports 154 may be controlled based on a size of the electrophoretic display device, thereby curing the electrophoretic display devices having various sizes.

FIG. 7C is a view illustrating a curing table 150 on which horizontally and vertically arranged supports 154 are provided with in a movable manner. As illustrated in FIG. 7C, in case where four pieces of electrophoretic display devices are loaded and cured, the supports with horizontal and vertical directions are moved and therefore a distance between the supports 154 to be loaded with the electrophoretic display device may be controlled based on a size of the electrophoretic display device while a distance between the supports 154 not to be loaded thereon with the electrophoretic display device being controlled by a minimum distance not to interfere with the electrophoretic display device, thereby effectively using the curing table 150.

Of course, the movement of those supports 154 may be applicable to a curing table 150 on which the supports 154 are horizontally and vertically arranged as well as to a curing table 150 on which the supports 154 are horizontally or vertically arranged in a line.

On the other hand, though a heating device 160 is provided to cure a seal material by applying heat to the seal material in the drawing, the seal material may be also cured by illuminating light such as ultra-violet rays. At this time, a ultra-violet-curing seal material is used instead of using a heat-curing seal material for the seal material, and an ultra-violet irradiation device is provided instead of a the heating device 160 to radiate ultra-violet rays on the violet-curing seal material, thereby curing the seal material.

As illustrated in FIG. 6, when heat (or ultra-violet rays) is applied by a heating device 160 (or ultra-violet irradiation device) in a state that an electrophoretic display device is loaded on the curing table 150, a seal material 129 for sealing the substrate 120 and the FPL film 130 starts to be cured. As the seal material is cured a stress is generated, and an edge region of the electrophoretic display device will be bent in an upward direction (i.e., in a direction getting away from the curing table 150) by the stress. However, in the present invention, a magnetic force will be exerted in a downward direction on the substrate 120, made of a metal plate, because the supports 154 for generating magnetic force, such as a magnetic resin, are formed on the curing table 150 placed thereon with the electrophoretic display device. This magnetic force will be exerted in a direction opposite to a stress caused by the curing of the seal material, and thus the electrophoretic display device will be prevented from being bent by the stress, thereby allowing the electrophoretic display device to maintain a flat state all the time.

Here, though the supports 154 are made of a magnetic resin having a low magnetism of about 400-1000 gauss in the foregoing description, the magnetism and material of the supports 154 are not substantially limited to those values. The supports 154 generate a magnetic force corresponding to a stress caused by the seal material in order to prevent the electrophoretic display device from being bent by the stress, and therefore, the electrophoretic display device may not be bent if the magnetic force by the supports 154 is greater than the stress caused by the seal material. However, the size of the stress caused by the seal material may be determined by various parameters, such as a type of the seal material, a curing speed of the seal material, a size of the electrophoretic display device, and the like, and accordingly, the magnetism of the supports 154 corresponding to the stress may vary based on the parameters.

As described above, in the present invention, thin-film transistors and electrodes, and the like, are formed on a plurality of panel regions 101 arranged on a mother substrate 100, respectively, in the TFT array process, and then each of the panel regions 101 is cut and divided into a plurality of display panels, and then a FPL film including an electronic ink film is attached to each of the divided display panels and its seal material is cured, thereby finishing an electrophoretic display device.

However, the present invention is not limited to an electrophoretic display device fabricated by those processes. In other words, the curing of a seal material in an electrophoretic display device according to the present invention may be not only implemented in an electrophoretic display device unit but also implemented in a mother substrate unit. Of course, the mother substrate itself will not be bent by a stress caused by the curing of a seal material if the curing of a seal material is implemented in a mother substrate unit, but the stress may be partially generated in a plurality of panel regions and thus the mother substrate may be partially rugged, and as a result, defective electrophoretic display devices may be caused when the mother substrate is divided into display panels. A method of curing a seal material in a mother substrate unit will be described below.

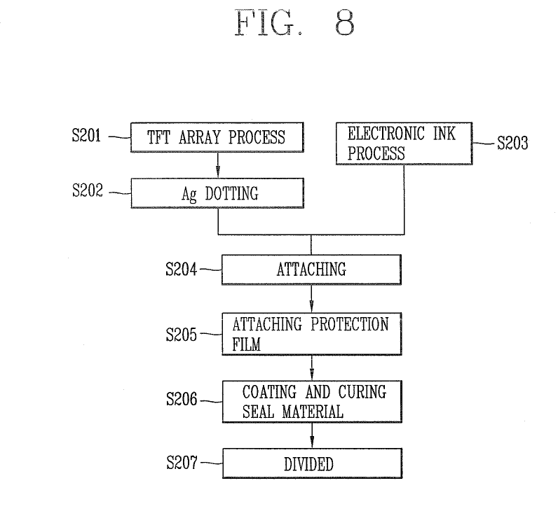

FIG. 8 is a view illustrating a method of fabricating an electrophoretic display device according to another embodiment of the present invention.

As illustrated in FIG. 8, first, in the TFT array process, thin-film transistors and various wirings and electrodes are formed on each of a plurality of panel regions 101 on a mother substrate made of a metal plate (S201). Subsequently, a silver dot is placed on a common line formed on each of the panel regions (S202).

On the other hand, in the electronic ink line, a transparent conductive material is laminated on a transparent sheet such as the PET to form a common electrode, and then an electronic ink film is attached to the common electrode to form a FPL film (S203).

Subsequently, a FPL film is attached to each of the panel regions formed on a mother substrate (S204), and then a protection film is attached again to a plurality of panel regions attached with the FPL film (S205).

Then, a seal material is coated between a plurality of panel regions on the mother substrate and the protection film attached to the panel regions, and then the seal material is cured by using a curing apparatus as illustrated in FIGS. 6 and 7 (S206). Then, the mother substrate attached with the FPL film and protection film is cut and divided into unit display panels to finish an electrophoretic display device (S207).

At this time, the seal material curing apparatus is formed in a large size and heat is applied or ultra-violet rays are radiated by a heating device or ultra-violet irradiation device, thereby curing the seal material coated on a plurality of mother substrates at the same time.

As described above, in the present invention, the support such as a magnetic resin is provided on a curing apparatus for curing a seal material in an electrophoretic display device to generate a magnetic force in a direction opposite to a stress generated when curing the seal material, thereby effectively preventing the electrophoretic display device from being bent by the stress.

In the foregoing detailed description of the present invention, although it has been described a particular structure of an electrophoretic display device, but this invention is not limited to such a structure. Furthermore, although the structure of a curing table or the shape or structure of a support has been disclosed in a particular shape or structure, this invention is not limited to such a structure or shape. If a magnetic force corresponding to a stress is generated to prevent the electrophoretic display device from being bent, then this invention may be applicable to various structures and shapes. In other words, other embodiments or modified embodiments according to the present invention using the basic concepts of the invention may be easily contrived by any person having ordinary skill in the art, and therefore, should be construed to be included in the scope of the right of the present invention.

What is claimed is:

1. An apparatus for curing a seal material in an electrophoretic display device, the apparatus comprising:
an electrophoretic display panel including a substrate made of metal and having thin-film transistors thereof, a front plane laminate (FPL) film made of a transparent sheet and an electronic ink film attached to the transparent sheet, a protection film attached to the FPL film, and a seal material formed between the substrate and the protection film for sealing the substrate and the protection film;
a curing table to be loaded with at least one electrophoretic display panel;
a curing unit for curing a seal material in an electrophoretic display panel loaded on the curing table; and
a support formed on the curing table for loading the electrophoretic display panel to apply a magnetic force in a direction opposite to a stress by the seal material to the electrophoretic display panel.

2. The apparatus of claim 1, wherein the electrophoretic display panel comprises a plurality of panel regions.

3. The apparatus of claim 1, wherein the support is made of a magnetic resin.

4. The apparatus of claim 1, wherein the curing unit comprises a heating device.

5. The apparatus of claim 1, wherein the curing unit comprises an ultra-violet irradiation device.

6. The apparatus of claim 1, wherein the support includes a plurality of the supports arranged vertically or horizontally.

7. The apparatus of claim 1, wherein the support includes a plurality of the supports arranged vertically and horizontally.

8. The apparatus of claim 6 or claim 7, wherein a distance between the supports is dependent upon a size of the electrophoretic display panel to be loaded thereon.

9. A method of fabricating an electrophoretic display device, the method comprising:
forming thin-film transistors and electrodes on each panel region of a mother substrate made of a metal plate including a plurality of panel regions;
forming a common electrode and adhering an electronic ink film on a transparent sheet to form a front plane laminate (FPL) film;
cutting the mother substrate to divide into a plurality of display panels;
adhering the FPL film and a protection film to the divided display panel;
coating a seal material on the display panel attached with the FPL film and protection film; and
loading the display panel coated with the seal material on a curing table formed with a support for applying a magnetic force to cure the seal material,
wherein a direction of the magnetic force applied by the support is opposite to the direction of a stress caused by the seal material.

10. A method of fabricating an electrophoretic display device, the method comprising:
forming thin-film transistors and electrodes on each panel region of a mother substrate made of a metal plate including a plurality of panel regions;
forming a common electrode and adhering an electronic ink film on each of a plurality of transparent sheets to form a plurality of front plane laminate (FPL) films;
adhering the FPL film and a protection film to each of a plurality of display panels formed on a mother substrate;
coating a seal material on each of the display panels of the mother substrate attached with the FPL film and protection film;
loading the mother substrate coated with the seal material on a curing table formed with a support for applying a magnetic force to cure the seal material; and
cutting the mother substrate to divide into a plurality of display panels,
wherein a direction of the magnetic force applied by the support is opposite to the direction of a stress caused by the seal material.

11. The method of claim 9 or 10, wherein the curing the seal material comprises applying heat or ultra-violet rays.
